(19) United States
(12) Patent Application Publication
(10) Pub. No.: US 2006/0014324 A1
(43) Pub. Date: Jan. 19, 2006

(54) Method and apparatus for cutting away excess synthetic resin from synthetic resin package of electronic component

(75) Inventor: Yuji Sakamoto, Kyoto-shi (JP)

Correspondence Address: HAMRE, SCHUMANN, MUELLER & LARSON, P.C., P.O. BOX 2902-0902, MINNEAPOLIS, MN, 55402, US

(73) Assignee: ROHM CO., LTD., Kyoto-shi (JP)

(21) Appl. No.: 11/216,257

(22) Filed: Aug. 31, 2005

Related U.S. Application Data
(62) Division of application No. 10/309,798, filed on Dec. 3, 2002.

(30) Foreign Application Priority Data
Apr. 12, 2001 (JP) 2001-370073

(51) Int. Cl. H01L 21/44

(52) U.S. Cl. 438/122

(57) ABSTRACT

A method is provided for cutting excess synthetic resin 7, which projects from a resin package 6 of an electronic component, at the root connected to the package, the excess synthetic resin being produced in molding the resin package. The excess synthetic resin 7 is cut by laying a thin plate 11 on an obverse surface of the resin package 7 while allowing the excess synthetic resin to penetrate therethrough, followed by moving a cutter 13 along and relative to the obverse surface of the thin plate 13. Alternatively, the cutting is performed by laying a cutter plate and a support plate on the obverse surface of the package 7 while allowing the excess synthetic resin to penetrate through the both plates followed by performing relative movement of the cutter plate.

### BACKGROUND OF THE INVENTION

1. Field of the Invention

The present invention relates to a method and apparatus for cutting away excess synthetic resin from a synthetic resin package for enclosing an electronic component such as a semiconductor chip. It more particularly relates to a method and apparatus for cutting away excess synthetic resin which is produced in an injection path of molten synthetic resin in molding the synthetic resin package.

2. Description of the Related Art

Recently, electronic components such as a semiconductor chip, a chip resistor or a chip capacitor mounted on an insulating substrate are enclosed in a package formed of a relatively soft thermoplastic synthetic resin such as polyamide resin.

Specifically, as shown in FIG. 1, a plurality of electronic components 2 such as semiconductor chips are mounted on an insulating substrate 1. As shown in FIG. 2, on the insulating substrate, a mold 3 is disposed which includes cavities 4 or respective electronic components 2. In this state, a synthetic resin such as polyamide resin in molten state is injected into each of the cavities 4 through a respective injection path 5, thereby molding a package 6 for enclosing each of the electronic components 2, as shown in FIGS. 3 and 4. Thereafter, excess synthetic resin 7 solidified in each injection path 5 is cut away from the resin package 6.

If a thermosetting synthetic resin such as epoxy resin is used for making the package 6, the excess synthetic resin 7 solidified in the injection path 5 can easily be removed from the resin package 6 by breaking the resin at its root connected to the package 6.

However, when a relatively soft thermoplastic synthetic resin such as polyamide resin is used, the excess synthetic resin 7 cannot be broken at the root connected to the resin package 6.

Conventionally, therefore, a cutter is used to cut away the excess synthetic resin 7 from the root connected to the package 6.

However, such cutting of the excess synthetic resin at the root using a cutter has a problem that the cutter often comes into contact with the package 6 to damage the package. Moreover, the height of the excess synthetic resin 7 after the cutting, i.e. the height from the upper surface of the resin package 6 to the cut surface is considerably large. Further, the height cannot be made uniform with respect to the plural packages.

### DISCLOSURE OF THE INVENTION

An object of the present invention to provide a method and an apparatus for solving the problems.

According to a first method aspect of the present invention, a method is provided for cutting away excess synthetic resin from a synthetic resin package of an electronic component. The excess synthetic resin projects from an obverse surface of the resin package as a result of solidification in an injection path of molten synthetic resin in molding the package. The method comprises the steps of laying a thin plate on the obverse surface of the resin package at a portion from which the excess synthetic resin projects so that the excess synthetic resin penetrates through the thin plate to project toward an obverse surface side of the thin plate, bringing a cutter into contact with the obverse surface of the thin plate, and relatively moving the thin plate and the package to the cutter in a direction along the obverse surface of the package.

According to a second method aspect of the present invention, a method is provided for cutting away excess synthetic resin from a synthetic resin package of an electronic component. The excess synthetic resin projects from an obverse surface of the resin package as a result of solidification in an injection path of molten synthetic resin in molding the package. The method comprises the steps of laying a cutter plate formed of a thin metal plate on the obverse surface of the resin package at a portion from which the excess synthetic resin projects so that the excess synthetic resin penetrates through the cutter plate to project toward an obverse surface side of the cutter plate, laying a support plate on the obverse surface of the cutter plate so that the excess synthetic resin penetrates through the support plate to project toward an obverse surface side of the support plate, and relatively moving the package and the support plate to the cutter plate in a direction along the obverse surface of the package.

According to a first apparatus aspect of the present invention, there is provided an apparatus for cutting away excess synthetic resin from a synthetic resin package of an electronic component. The excess synthetic resin projects from an obverse surface of the resin package as a result of solidification in an injection path of molten synthetic resin in molding the package. The apparatus comprises a thin plate for laying on the obverse surface of the resin package at a portion from which the excess synthetic resin projects so that the excess synthetic resin penetrates through the thin plate, a cutter for coming into contact with an obverse surface of the thin plate, and means for relatively moving the thin plate and the package to the cutter in a direction along the obverse surface of the package.

According to a second apparatus aspect of the present invention, there is provided an apparatus for cutting away excess synthetic resin from a synthetic resin package of an electronic component. The excess synthetic resin projects from an obverse surface of the resin package as a result of solidification in an injection path of molten synthetic resin in molding the package. The apparatus comprises a cutter plate formed of a thin metal plate for laying on the obverse surface of the resin package at a portion from which the excess synthetic resin projects so that the excess synthetic resin penetrates through the cutter plate, a support plate for laying on an obverse surface of the cutter plate so that the excess synthetic resin penetrates through the support plate, and means for relatively moving the package and the support plate to the cutter plate in a direction along the obverse surface of the package.

As described above, a thin plate is laid on the obverse surface of the resin package at a portion from which the excess synthetic resin projects so that the excess synthetic resin penetrates through the thin plate to project toward an obverse surface side of the thin plate, and then the thin plate and the package, and a cutter held in contact with the obverse surface of the thin plate are moved relative to each other in a direction along the obverse surface of the package. With this method, the excess synthetic resin projecting from the package can be cut reliably at its root by the cutter which moves relative to the thin plate in contact with the obverse surface of the plate.

In the cutting, the thin plate prevents the cutter from contacting the package so that the obverse surface of the package is not damaged. Further, the remaining excess synthetic resin can be generally equal to each other in height from the upper surface of the package, which is generally equal to the thickness of the thin plate and is therefore relatively small.

By forming the thin plate from a metal, its endurance is enhanced, and the resistance in moving the cutter relative to and in contact with the thin plate can be considerably decreased. When a single thin plate is laid over a plurality of packages, the excess synthetic resin pieces projecting from the packages can collectively be cut at their roots, which enhances the work efficiency and reduces the cost required for the cutting work.

Further, as described above, in the method according to a second aspect, a cutter plate formed of a thin metal plate is laid on the obverse surface of the resin package at a portion from which the excess synthetic resin projects so that the excess synthetic resin penetrates through the cutter plate to project toward an obverse surface side of the cutter plate, a support plate is laid on the obverse surface of the cutter plates so that the excess synthetic resin penetrates through the support plate to project toward an obverse surface side of the supports plate, and the package and the support plate, and the cutter plate are moved relative to each other in a direction along the obverse surface of the package. With this method, the excess synthetic resin piece projecting from the package can reliably be cut at its root in a guillotine-like manner by the relative movement of cutter plate sandwiched between the package and the support plate.

Since the cutting is performed by the movement of the cutter plate relative to the package and the support plate, there is no possibility that the surface of the package is damaged. Further, it is possible to cut away the excess synthetic resin piece almost completely so that its height from the upper surface of the package becomes almost zero. Further, since the thin plate is formed of a metal, the plate has enhanced endurance, and the resistance in the relative movement of the cutter is considerably decreased.

Also in this case, when a single cutter plate and a single support plate are laid over a plurality of packages, the excess synthetic resin pieces projecting from the packages can collectively be cut at their roots, which enhances the work efficiency and reduces the cost required for the cutting work. Further, by making the cutter plate from a thin metal plate, its endurance is enhanced, and the resistance in moving the cutter plate relative to and in contact with the support plate can be considerably decreased.

Other objects, features and advantages of the present invention will become clearer from the description of the preferred embodiment given below.

### BRIEF DESCRIPTION OF THE DRAWINGS

FIG. 1 is a perspective view illustrating an insulating substrate on which a plurality of electronic components are mounted.

FIG. 2 is a vertical sectional view illustrating molding of packages for sealing the electronic components on the insulating substrate.

FIG. 3 is a perspective view illustrating the insulating substrate formed with packages.

FIG. 4 is an enlarged sectional view taken along lines IV-IV in FIG. 3.

FIG. 5 is a perspective view illustrating a first embodiment of the present invention.

FIG. 6 is an enlarged sectional view taken along lines VI-VI in FIG. 5.

FIG. 7 is a perspective view illustrating a second embodiment of the present invention.

FIG. 8 is an enlarged sectional view taken along lines VIII-VIII in FIG. 7.

### DETAILED DESCRIPTION OF THE PREFERRED EMBODIMENTS

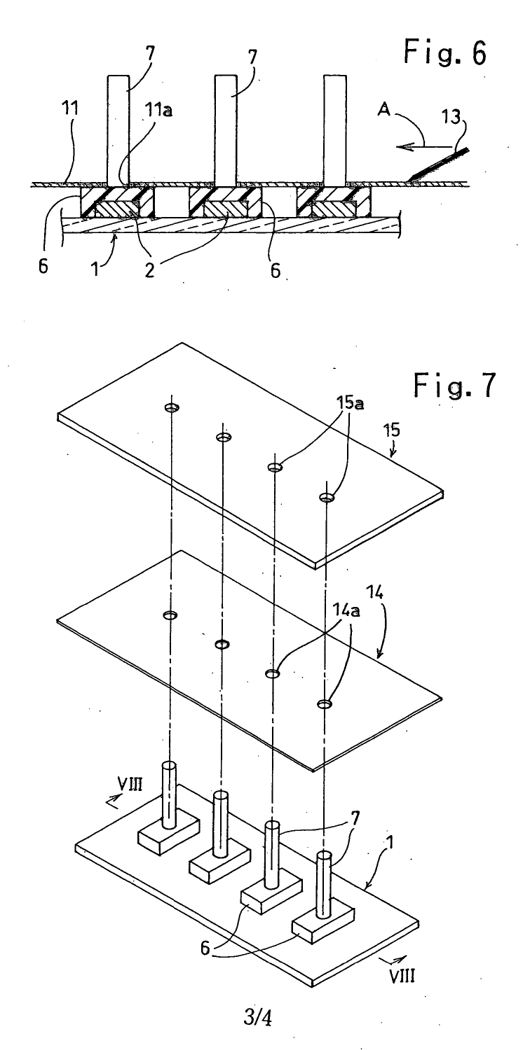

Preferred embodiments of the present invention will be described below with reference to the accompanying drawings. FIGS. 5 and 6 illustrate a first embodiment of the present invention.

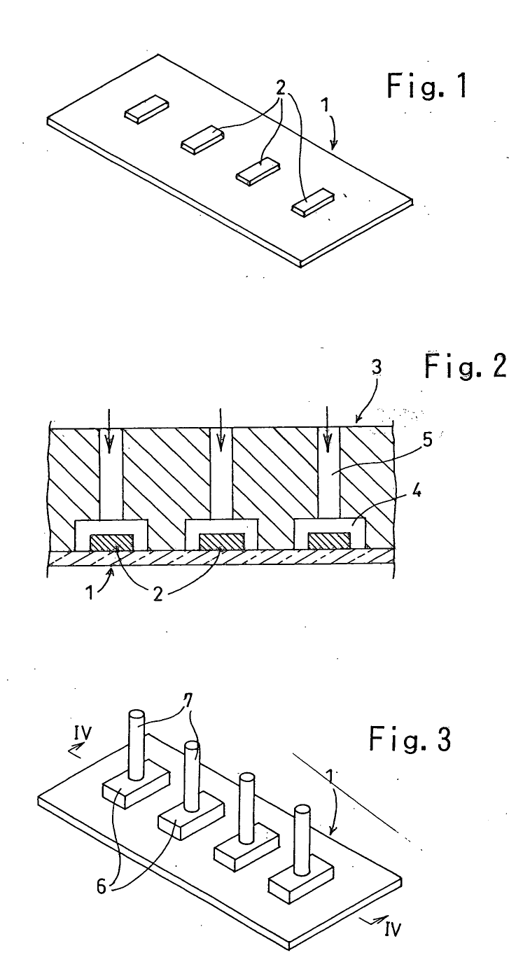

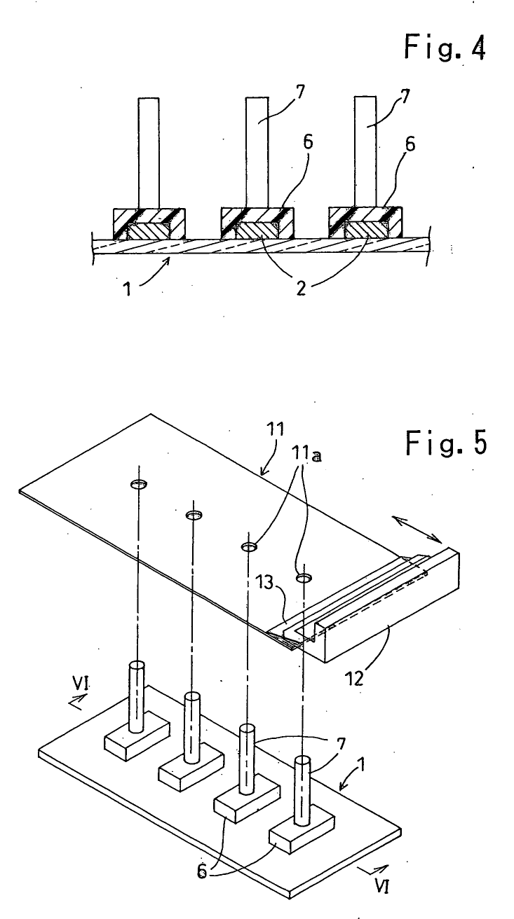

In these figures, as is in FIGS. 1-4, indicated by the reference numeral 1 is an insulating substrate having an upper surface provided with a plurality of packages 6 formed by molding a thermoplastic synthetic resin such as polyamide resin. Each of the packages 6 is provided, on the upper surface thereof, with an upwardly projecting excess synthetic resin piece 7, which has been formed in an injection path 5 for the molten synthetic resin in molding the resin package 6.

The reference numeral 11 indicates a thin plate which is formed of a metal such as stainless steel or spring steel to have a thickness of 0.05-0.1 mm.

The thin plate 11 is laid on the packages 6 formed on the insulating substrate 1 as aligned in a same plane.

The thin plate 11 is formed, in advance, with holes 11a at locations corresponding to the excess synthetic resin pieces 7 on the packages 6 for allowing the resin pieces 7 to extend therethrough. Thus, the excess synthetic resin pieces penetrate the thin plate 11 to project upward from the plate.

Subsequently, a cutter 13 formed of a thin metal plate and attached to a holder 12 is disposed on the thin plate 11 so that the cutter 13 comes into contact with the upper surface of the thin plate 13. Then, as indicated by an arrow A in FIG. 6, with the insulating substrate 1 and the thin plate 11 kept movable, the cutter 13 is moved in the direction along the upper surfaces of the packages 6 utilizing a non-illustrated horizontal moving mechanism.

By such movement of the cutter 13 in contact with the upper surface of the thin plate 11, each of the excess synthetic resin pieces 7 extending from the packages 6 can be cut reliably at its root, while the thin plate 13 prevents the cutter 13 from contacting the packages 6. Further, the resulting excess synthetic resin pieces are generally equal to each other in height from the upper surfaces of the packages 6, which is generally equal to the thickness of the thin plate 11 and is therefore relatively small.

In cutting, instead of moving the cutter 13 alone with the insulating substrate 1 and the thin plate 11 kept unmoved, the insulating substrate 1 together with the thin plate 13 may be moved with the cutter 13 kept unmoved. Alternatively, the insulating substrate 1 together with the thin plate 11, and the cutter 13 may be moved in opposite directions to each other.

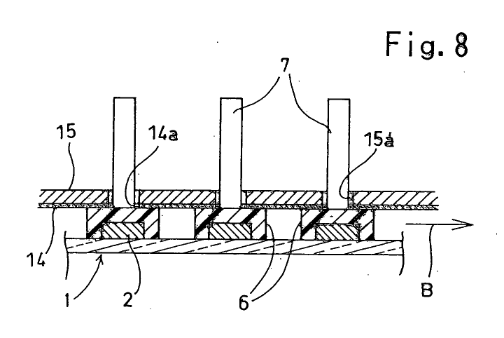

FIGS. 7 and 8 illustrate a second embodiment of the present invention.

In these figures, as is in FIGS. 1-4, indicated by the reference numeral 1 is an insulating substrate having an upper surface provided with a plurality of packages 6 formed by molding a thermoplastic synthetic resin such as polyamide resin. Each of the packages 6 is provided, on the upper surface thereof, with an upwardly projecting excess synthetic resin piece 7, which has been formed in molding the resin package 6.

The reference numeral 14 indicates a thin cutter plate which is formed of a metal such as stainless steel or spring steel to have a thickness of 0.05-0.1 mm, whereas the reference numeral 15 indicates a support plate formed of a metal.

The cutter plate 14 is laid on the packages 6 formed on the insulating substrate 1 as aligned in a same plane, and the support plate 15 is laid on the upper surface of the cutter plate 14.

The cutter plate 14 and the support plate 15 are formed, in advance, with holes 14a and 15a, respectively, at locations corresponding to the excess synthetic resin pieces 7 on the packages 6 for allowing the resin pieces 7 to extend therethrough. Thus, the excess synthetic resin pieces penetrate the cutter plate 11 and the support plate 15 to project upward from the support plate 15.

Subsequently, as indicated by an arrow B in FIG. 8, with the insulating substrate 1 and the support plate 15 kept fixed, the cutter plate 14 alone is moved in the direction along the upper surfaces of the packages 6 utilizing a non-illustrated horizontal moving mechanism.

By such movement of the cutter plate 14 as sandwiched between the packages and the support plate, the excess synthetic resin pieces 7 extending from the packages 6 can reliably be cut at their roots collectively (simultaneously) in a guillotine-like manner. Since the cutting is performed by moving the cutter plate 14 along the upper surfaces of the packages 6, there is no possibility that the surfaces of the packages 6 are damaged. Further, it is possible to cut away each excess synthetic resin piece 7 almost completely so that its height from the upper surface of the package 6 becomes almost zero.

Also in this way of cutting, instead of moving the cutter plate 14 alone with the insulating substrate 1 and the support plate 15 kept unmoved, the insulating substrate 1 together with the support plate 15 may be moved with the cutter plate 14 kept unmoved. Alternatively, the insulating substrate 1 together with the support plate 15, and the cutter plate 14 may be moved in opposite directions to each other.

Further, in each of the embodiments described above, the plural packages 6 are formed on the insulating substrate 1 as aligned in a same plane. However, the present invention is not limited to such a case but is applicable to a plurality of packages provided on a lead frame as aligned in a same plane. The invention is applicable even to a plurality of packages molded separately by aligning the packages in a same plane.

Moreover, in both of the above-described embodiments, the cutting is performed with the excess synthetic resin pieces 7 on the packages 6 on the insulating substrate 1 oriented upward. However, the present invention is not limited thereto, and the cutting may be performed with the excess synthetic resin pieces 7 on the packages 6 on the insulating substrate 1 oriented downward.

1-2. (canceled)

3. A method for cutting away excess synthetic resin from a synthetic resin package of an electronic component, the excess synthetic resin projecting from an obverse surface of the resin package as a result of solidification in an injection path of molten synthetic resin in molding the package, the method comprising the steps of: laying a cutter plate on the obverse surface of the resin package at a portion from which the excess synthetic resin projects so that the excess synthetic resin penetrates through the cutter plate to project toward an obverse surface side of the cutter plate; laying a support plate on the obverse surface of the cutter plate so that the excess synthetic resin penetrates through the support plate to project toward an obverse surface side of the support plate; and relatively moving the package and the support plate to the cutter plate in a direction along the obverse surface of the package.

4. The method for cutting away excess synthetic resin from a synthetic resin package of an electronic component according to claim 3, wherein a single cutter plate and a single support plate are laid over a plurality of packages aligned in a same plane.

5. (canceled)

6. An apparatus for cutting away excess synthetic resin from a synthetic resin package of an electronic component, the excess synthetic resin projecting from an obverse surface of the resin package as a result of solidification in an injection path of molten synthetic resin in molding the package, comprising: a cutter plate for laying on the obverse surface of the resin package at a portion from which the excess synthetic resin projects so that the excess synthetic resin penetrates through the cutter plate; a support plate for laying on an obverse surface of the cutter plate so that the excess synthetic resin penetrates through the support plate; and means for relatively moving the package and the support plate to the cutter plate in a direction along the obverse surface of the package.

7. The apparatus for cutting away excess synthetic resin from a synthetic resin package of an electronic component according to claim 6, wherein the support plate is formed of metal.

8. The apparatus for cutting away excess synthetic resin from a synthetic resin package of an electronic component according to claim 6, wherein the cutter plate comprises a thin metal plate.
